(19) United States
(12) Patent Application Publication
(10) Pub. No.: US 2011/0127658 A1
(43) Pub. Date: Jun. 2, 2011

(54) Muti Thickness Lead Frame

(75) Inventor: Chung Hsing Tzu, Taiei County (TW)

(73) Assignee: Great Team Backend Foundry, Inc., British Virgin Islands (GB)

(21) Appl. No.: 12/954,852

(22) Filed: Nov. 27, 2010

Related U.S. Application Data
(60) Provisional application No. 61/264,788, filed on Nov. 28, 2009.

(51) Int. Cl. H01L 23/495

(52) U.S. Cl. 257/675; 257/E23.051

(57) ABSTRACT

A lead frame includes a lead frame 11 made by a rolled single-layer of copper and has a lead portion and a chip support portion. The thickness of the lead portion is the same as that of the chip support portion. A heat dispensing plate made of Aluminum is connected to the chip portion and has a rough surface which is not connected with the lead frame. The lead frame is applied by Laser Diode To Package or metal-Oxide-Semiconductor Field Effect Transistor has high efficiency of heat dispensing and low manufacturing cost, and is suitable for different types of chips.

### FIELD OF THE INVENTION

The present invention relates to a lead frame, and more particularly, to a lead frame having high efficiency of heat dispensing and low manufacturing cost.

### BACKGROUND OF THE INVENTION

Their are three types of conventional lead frame after being processed by Metal-Oxide-Semiconductor Field Transistor and Laser Diode To Package, and the first one is shown in FIG. 1 and generally includes a two-layer thicknesses copper plate which is rolled and pressed to have a lead portion 1 and a chip support portion 2, wherein the thickness of the chip support portion 2 is thicker than that of the lead portion 1. When a chip is bonded on the chip support portion 2, the thicker chip support portion 2 removes the heat generated from the chip. However, the thicker copper plate is expensive and the lead frame requires complicate forging tools which also increases the manufacturing cost.

The second one is to use a single-layer copper plate which is rolled to have a lead portion 3 and a chip support portion 4, wherein the thickness of the chip support portion 4 is the same as that of the lead portion 3 as shown in FIG. 2, such that the cost of the copper and manufacturing is reduced. Nevertheless, the efficiency of heat dispensing is unsatisfied and the produce defect rate is increased. The third one is to make the lead portion 3 by a planar material and the chip support portion is replaced by an Aluminum part 5 which is connected with the lead portion 3 by way of rivet joint methodology as shown in FIG. 3 to reduce the manufacturing and copper material cost. However, the Aluminum cannot reach the same heat dispensing efficiency as the copper has, and this especially important for those chips of high operation speed.

The present invention intends to provide a lead frame which has less manufacturing cost and higher heat dispensing efficiency than all of the conventional lead frames.

### SUMMARY OF THE INVENTION

The present invention relates to a lead frame and comprises a lead frame made by a single-layer of copper and having a lead portion and a chip support portion. The thickness of the lead portion is the same as that of the chip support portion. A heat dispensing plate is connected to the chip portion.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is a cross sectional view of the conventional lead frame;

FIG. 2 is a cross sectional view of another conventional lead frame;

FIG. 3 is a cross sectional view of yet another conventional lead frame;

FIG. 4 is a cross sectional view to show a chip is connected to the conventional lead frame as shown in FIG. 3;

FIG. 5 is a cross sectional view to show a chip is connected to the conventional lead frame as shown in FIG. 2;

FIG. 6 is a cross sectional view of the lead frame of the present invention;

FIG. 7 is a cross sectional view of a preferable embodiment of the lead frame of the present invention;

FIG. 8 is a cross sectional view to show the combination of the lead frame of the present invention and the chip, and

FIG. 9 is a cross sectional view to show the combination of another embodiment of the lead frame of the present invention and the chip.

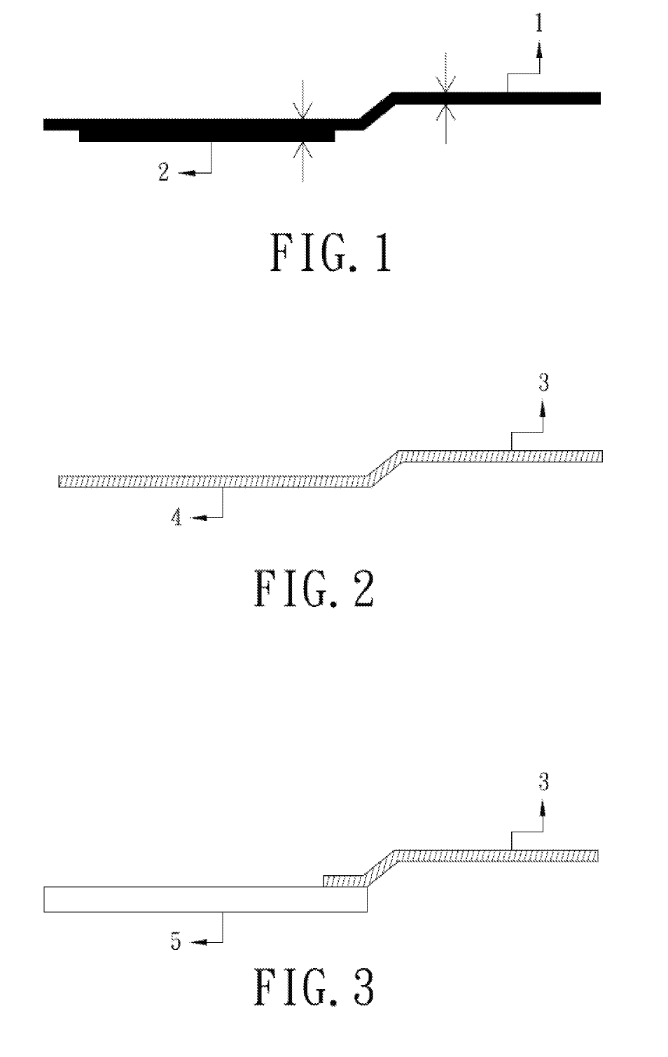

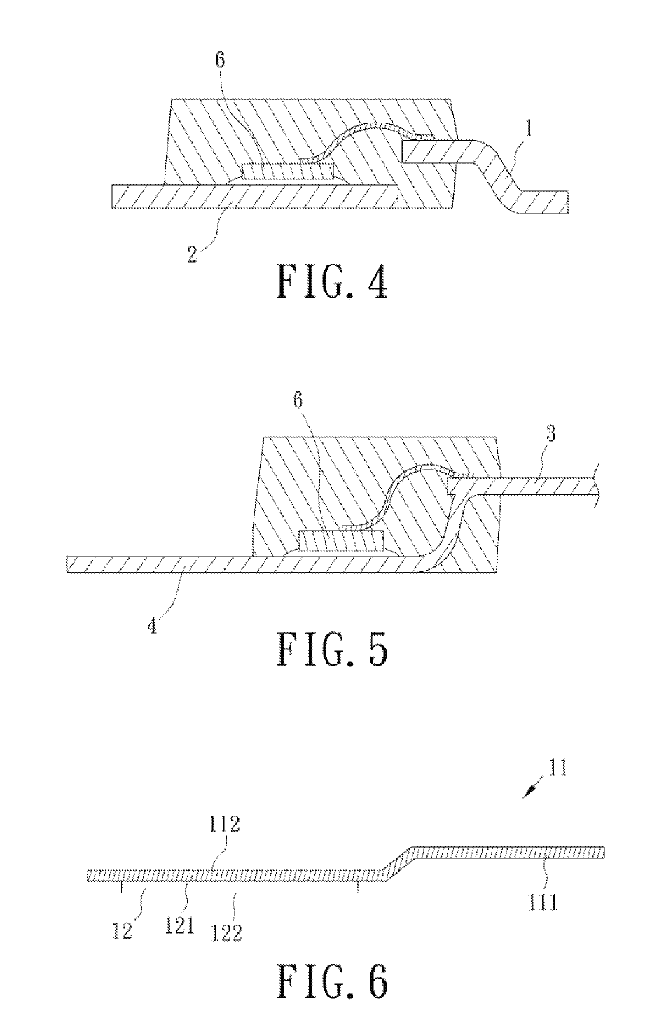

### DETAILED DESCRIPTION OF THE PREFERRED EMBODIMENT

Referring to FIGS. 6 and 8, the lead frame 11 of the present invention is made by a single-layer of copper which is rolled to have a lead portion 111 and a chip support portion 112. The thickness of the lead portion 111 is the same as that of the chip support portion 112. The chip support portion 112 is to be bonded with the chip 14.

A heat dispensing plate 12, preferably made by Aluminum is rolled to form a plate-like part and includes a connection surface 121 and a rough surface 122, wherein the connection surface 121 is connected to the chip portion 112 by way of eutectic and the opposite side of the connection surface 121 is the rough surface 122 which increases the heat dispensing area.

In the process of Laser Diode To Package for the Metal-Oxide-Semiconductor Field Effect Transistor, one side of the chip support portion 112 of the lead frame 11 is connected to the connection surface 121 of the heat dispensing plate 12 by way of compress pressure and ultrasonic power joint methodology. The other side of the chip support portion 112 that is not connected to the heat dispensing plate 12 is welded to the chip 14 by bonding agent 13. The two ends 151, 152 of the connector 15 are connected to the chip 14 and the lead portion 111 respectively, so that the chip 14 is electrically connected to the lead portion 111. In the final step, the combination of the above mentioned components are processed by the Laser Diode To Package. The connector 15 is made of Gold, Copper or Aluminum, and the connector 15 is a linear part, a strip or a plate.

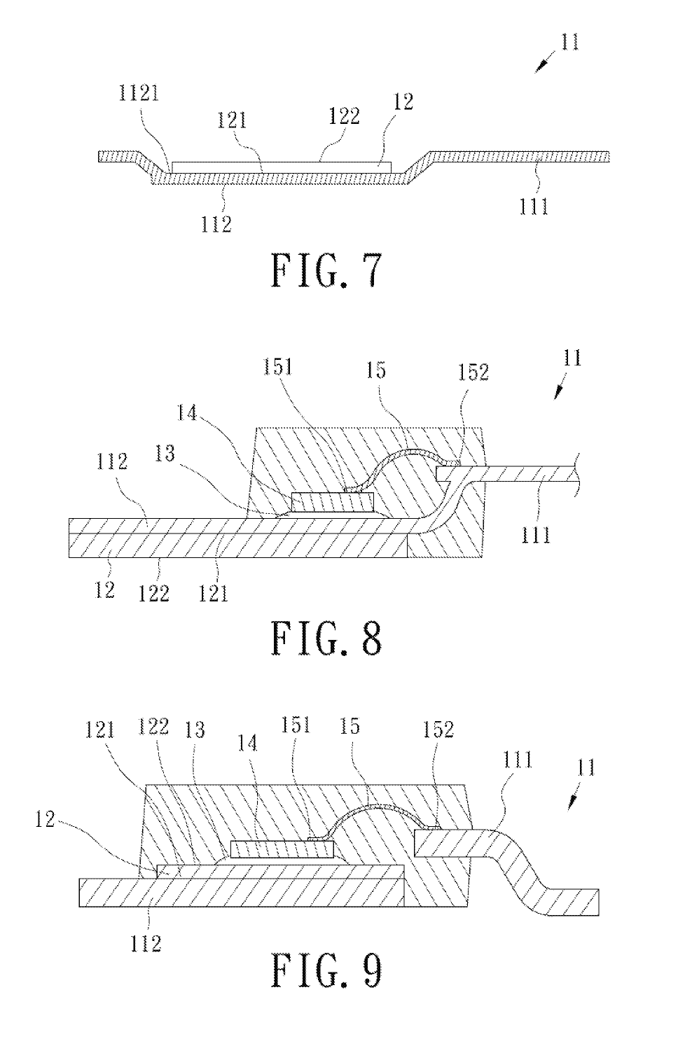

Referring to FIG. 7 which shows another embodiment, wherein the difference is that the lead frame 11 is a single-layer copper plate which is rolled to form as a recessed plate. The chip support portion 112 is located at the lowest position of the recessed area and the heat dispensing plate 12 is bonded to the recess 1121 of the lead frame 11 by the connection surface 121 of the heat dispensing plate 12. The chip 14 is then bonded to the heat dispensing plate 12 by bonding agent 13.

Referring to FIG. 9 which shows yet another embodiment, wherein the difference is that the lead frame 11 is a single-layer copper plate which is rolled to have the lead portion 111 and the chip support portion 112. The lead portion 111 and the chip support portion 112 are two separated parts. The chip support portion 112 is connected with the Aluminum made heat dispensing plate 12 by way of compress pressure and ultrasonic power bonding and the chip 14 is bonded to the heat dispensing plate 12. The connector 15 is finally connected between the lead portion 111 and the chip 14 to form a circuit. In the final step, the combination of the above mentioned components are processed by the Laser Diode To Package. Alternatively, the chip support portion 112 and the heat dispensing plate 12 can be exchanged to each other, and the surface of the heat dispensing plate 12 that is not connected with the chip support portion 112 is made to be a rough surface to increase the heat dispensing area.

It is noted that the shape and material of the lead frame 11 and the heat dispensing plate 12 can be varied according to practical needs.

While we have shown and described the embodiment in accordance with the present invention, it should be clear to those skilled in the art that further embodiments may be made without departing from the scope of the present invention.

What is claimed is:

1. A lead frame comprising:
a lead frame made by a single-layer of copper and having a lead portion and a chip support portion, a thickness of the lead portion being the same as that of the chip support portion, and
a heat dispensing plate connected to the chip portion.

2. The lead frame as claimed in claim 1, wherein the heat dispensing plate has a surface that is not connected with the chip support portion is a rough surface.

3. The lead frame as claimed in claim 1, wherein the lead frame and the heat dispensing plate is connected with each other by way of compress pressure and ultrasonic power bonding methodology.

4. The lead frame as claimed in claim 1, wherein the heat dispensing plate is made of Aluminum.

5. The lead frame as claimed in claim 1, wherein the lead portion and the chip support portion are an integral part or two separated parts.

6. The lead frame as claimed in claim 1, wherein the heat dispensing plate is connected to a top or a bottom of the chip support portion.

7. A lead frame comprising:
a lead frame made by a single-layer of copper and having a lead portion and a chip support portion, a thickness of the lead portion being the same as that of the chip support portion;
a heat dispensing plate connected to the chip portion;
a chip bonded to the chip portion or the heat dispensing plate by bonding agent, and
a connector having two ends thereof bonded to the chip and the lead portion respectively so that the chip is electrically connected to the lead portion.

8. The lead frame as claimed in claim 7, wherein the heat dispensing plate has a surface that is not connected with the chip support portion is a rough surface.

9. The lead frame as claimed in claim 7, wherein the lead frame and the heat dispensing plate is connected with each other by way of compress pressure and ultrasonic power bonding methodology.

10. The lead frame as claimed in claim 7, wherein the heat dispensing plate is made of Aluminum.

11. The lead frame as claimed in claim 7, wherein the lead portion and the chip support portion are an integral part or two separated parts.

12. The lead frame as claimed in claim 7, wherein the heat dispensing plate is connected to a top or a bottom of the chip support portion.

13. The lead frame as claimed in claim 7, wherein the connector is made of Gold, Copper or Aluminum.

14. The lead frame as claimed in claim 7, wherein the connector is a linear part, a strip or a plate.

15. A lead frame comprising:
a lead frame made by a single-layer of copper and having a lead portion and a chip support portion, a thickness of the lead portion being the same as that of the chip support portion;
a heat dispensing plate connected to the chip portion;
a chip having a layer of metal material which is connected to the chip portion or the heat dispensing plate by way of compress pressure and ultrasonic power bonding methodology, and
a connector having two ends thereof welded to the chip and the lead portion respectively so that the chip is electrically connected to the lead portion.

16. The lead frame as claimed in claim 15, wherein the heat dispensing plate has a surface that is not connected with the chip support portion is a rough surface.

17. The lead frame as claimed in claim 15, wherein the lead frame and the heat dispensing plate is connected with each other by way of compress pressure and ultrasonic power bonding methodology.

18. The lead frame as claimed in claim 15, wherein the heat dispensing plate is made of Aluminum.

19. The lead frame as claimed in claim 15, wherein the lead portion and the chip support portion are an integral part or two separated parts.

20. The lead frame as claimed in claim 15, wherein the heat dispensing plate is connected to a top or a bottom of the chip support portion.

21. The lead frame as claimed in claim 15, wherein the connector is made of Gold, Copper or Aluminum.

22. The lead frame as claimed in claim 15, wherein the connector is a linear part, a strip or a plate.
